(19) United States
(12) Patent Application Publication
(10) Pub. No.: US 2005/0077589 A1
(43) Pub. Date: Apr. 14, 2005

(54) Light receiving element for blue rays and method for manufacturing the same

(75) Inventors: Jung-Chul Gong, Seoul (KR); Kyoung-Soo Kwon, Kyunggi-Do (KR); Joo-Yul Ko, Kyunggi-Do (KR); Sang-Suk Kim, Kyunggi-Do (KR)

Correspondence Address: MORGAN LEWIS & BOCKIUS LLP, 1111 PENNSYLVANIA AVENUE NW, WASHINGTON, DC, 20004, US

(73) Assignee: Samsung Electro-Mechanics Co., Ltd.

(21) Appl. No.: 10/725,441

(22) Filed: Dec. 3, 2003

(30) Foreign Application Priority Data
Oct. 14, 2003 (KR) 2003-71436

(51) Int. Cl. H01L 27/14

(52) U.S. Cl. 257/458

(57) ABSTRACT

Disclosed are a light receiving element for blue rays and a method for manufacturing the light receiving element, more particularly, it is to provide a light receiving element for blue rays, of which a junction depth becomes shallow so as to easily receive the blue rays having a short wavelength with a short penetration depth, and a method for manufacturing the light receiving element.

### BACKGROUND OF THE INVENTION

1. Field of the Invention

The present invention relates to a light receiving element for blue rays and a method for manufacturing the same, and more particularly to a light receiving element for blue rays, of which a junction depth becomes shallow so as to easily receive the blue rays having a short wavelength with a short penetration depth, and a method for manufacturing the light receiving element.

2. Description of the Related Art

Generally, an optical pick-up apparatus for reading CDs or DVDs comprises a photo detector integrated circuit (PDIC) including an optical recording medium intensively storing data by light projected from a laser diode, an photoelectric transducer for converting an optical signal reflected by an optical disk to an electric signal, and an amplifier for amplifying and then outputting the electric signal inputted from the photoelectric transducer.

Hereinafter, with reference to FIGS. 1a to 1h, a process for manufacturing a photo diode used as the above-described photoelectric transducer will be described in detail.

First, as shown in FIG. 1a, a p⁺ barrier layer (PBL) 2 serving as an anode for receiving a power supplied from the exterior is formed on a substrate 1.

As shown in FIG. 1b, a p-type epitaxial layer 3 is grown on the p⁺ barrier layer 2 for forming a depletion layer area for generating pairs of electrons-holes (EHP) corresponding to energy of incident light from the exterior. Then, as shown in FIG. 1c, a p⁺ well layer 4, which is electrically connected to the p⁺ barrier layer 2, is selectively formed on the p-type epitaxial layer 3.

After the formation of the p⁺ well layer 4, as shown in FIG. 1d, the p-type epitaxial layer 3 is oxidized, thus allowing an oxide layer 5 to be formed thereon. Then, the oxide layer 5 is window-etched, thus allowing window areas to be formed thereon.

Thereafter, as shown in FIGS. 1e to 1g, a buffer oxide layer 6 is formed by depositing a buffer oxide on the window areas, and a designated impurity, more specifically, an ion such as arsenic (As), is injected into the buffer oxide layer 6. Then, an n⁺ layer 7 serving as a cathode is formed on the p-type epitaxial layer 3 by a drive-in process.

After the formation of the n⁺ layer 7 serving as the cathode as described above, as shown in FIG. 1h, the buffer oxide layer 6 is removed from the window areas, and external electrode areas for performing electrical connection with the n⁺ layer 7 and the p⁺ well layer 4 formed on the p-type epitaxial layer 3 are formed by a masking step. Then, metal electrodes 8 are formed on the external electrode areas by depositing metal on the external electrode areas.

In the photoelectric transducer for the photo detector integrated circuit, which is obtained by the above-described manufacturing process, a depletion layer is formed along an PN (or NP) junction layer by applying a reverse bias voltage to the photo diode having an PN or NP junction, as shown in FIG. 2.

Thereinafter, in case that energy of external light having a designated wavelength is provided to the depletion layer, pairs of electrons-holes are generated in the depletion layer, thus creating photo current in the depletion layer and allowing an optical signal to be converted into an electric signal.

In the above-described photo diode, as shown in FIG. 3, an optical signal having a long wavelength of 780 nm with an optical penetration depth of 8.3 μm easily reaches the depletion layer, thus having good optical efficiency. On the other hand, an optical signal, for blue rays, having a short wavelength of 405 nm with an optical penetration depth of 0.2 μm does not reach the depletion layer, thus having poor optical efficiency.

That is, since the thickness of the n⁺ layer 7, i.e., the distance from the surface to the PN junction, is approximately 0.5 μm, and the optical signal provided from the exterior, for blue rays, having a short wavelength of 405 nm with an optical penetration depth of 0.2 μm does not easily reach the depletion layer, the photo diode shown in FIG. 2 has poor optical efficiency.

### SUMMARY OF THE INVENTION

Therefore, the present invention has been made in view of the above problems, and it is an object of the present invention to provide a light receiving element for blue rays, of which a junction depth becomes shallow so as to easily receive the blue rays having a short wavelength with a short penetration depth, and a method for manufacturing the light receiving element.

In accordance with one aspect of the present invention, the above and other objects can be accomplished by the provision of a light receiving element for blue rays comprising: a substrate; a p⁺ barrier layer (PBL) buried in the substrate by a designated depth for serving as an anode for receiving a power provided from the exterior; a p-type epitaxial layer formed on the p⁺ barrier layer (PBL) by epitaxial growth, and provided with a depletion layer area for generating pairs of electrons-holes (EHP) corresponding to energy of incident light from the exterior; a p⁺ well layer formed on designated areas of the p-type epitaxial layer, formed by masking, by injecting a designated impurity in an ion state into the designated areas, and electrically connected to the p⁺ barrier layer (PBL); a polysilicon layer formed by depositing polysilicon on window areas formed by window-etching an oxide layer obtained by oxidizing the p-type epitaxial layer; and an n⁺ shallow junction layer diffused into a designated depth of the p-type epitaxial layer by implanting a designated impurity ion into the polysilicon layer and then heating the polysilicon layer for serving as a cathode for transmitting an electrical signal obtained by photoelectric conversion to the exterior.

In accordance with a further aspect of the present invention, there is provided a light receiving element for blue rays comprising: a substrate; a p⁺ barrier layer (PBL) buried in the substrate by a designated depth for serving as an anode for receiving a power provided from the exterior; a p-type epitaxial layer formed on the p⁺ barrier layer (PBL) by epitaxial growth, and provided with a depletion layer area for generating pairs of electrons-holes (EHP) corresponding to energy of incident light from the exterior; a p⁺ well layer formed on designated areas of the p-type epitaxial layer, formed by masking, by injecting a designated impurity in an ion state into the designated areas, and electrically connected to the p⁺ barrier layer (PBL); a polysilicon layer formed by depositing polysilicon, doped with an impurity ion, on window areas formed by window-etching an oxide layer obtained by oxidizing the p-type epitaxial layer; and an n⁺ shallow junction layer diffused into a designated depth of the p-type epitaxial layer by heating the polysilicon layer for serving as a cathode for transmitting an electrical signal obtained by photoelectric conversion to the exterior.

In accordance with another aspect of the present invention, there is provided a method for manufacturing a light receiving element for blue rays comprising the steps of: (a) forming a p⁺ barrier layer (PBL) for serving as an anode for receiving a power provided from the exterior on a substrate; (b) growing a p-type epitaxial layer, provided with a depletion layer area for generating pairs of electrons-holes (EHP) corresponding to energy of incident light from the exterior, on the p⁺ barrier layer (PBL); (c) forming a p⁺ well layer, electrically connected to the p⁺ barrier layer (PBL), on the p-type epitaxial layer; (d) forming an oxide layer by oxidizing the p-type epitaxial layer; (e) forming a polysilicon layer by depositing polysilicon on overlapped areas between window areas formed by window-etching the oxide layer and the oxide layer by a designated distance; (f) implanting a designated impurity ion into the polysilicon layer; (g) forming an n⁺ shallow junction layer into a designated depth of the p-type epitaxial layer by heating the polysilicon layer provided with the implanted impurity ion; and (h) etching the polysilicon layer formed on the overlapped areas between window areas and the oxide layer by the designated distance.

In accordance with yet another aspect of the present invention, there is provided a method for manufacturing a light receiving element for blue rays comprising the steps of: (a) forming a p⁺ barrier layer (PBL) for serving as an anode for receiving a power provided from the exterior on a substrate; (b) growing a p-type epitaxial layer, provided with a depletion layer area for generating pairs of electrons-holes (EHP) corresponding to energy of incident light from the exterior, on the p⁺ barrier layer (PBL); (c) forming a p⁺ well layer, electrically connected to the p⁺ barrier layer (PBL), on the p-type epitaxial layer; (d) forming an oxide layer by oxidizing the p-type epitaxial layer; (e) forming a polysilicon layer by depositing polysilicon, doped with an impurity ion, on overlapped areas between window areas formed by window-etching the oxide layer and the oxide layer by a designated distance; (f) forming an n⁺ shallow junction layer into a designated depth of the p-type epitaxial layer by heating the polysilicon layer doped with the impurity ion; and (g) etching the polysilicon layer formed on the overlapped areas between window areas and the oxide layer by the designated distance.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1h are cross-sectional views illustrating a process for manufacturing a photoelectric transducer used in a conventional photo detector integrated circuit (PDIC);

FIG. 2 is a schematic view of the photoelectric transducer, to which a reverse bias voltage is applied;

FIG. 3 is a graph illustrating variation in optical penetration depth according to variation in optical wavelength;

FIG. 4 is a longitudinal-sectional view of a light receiving element for blue rays in accordance with one embodiment of the present invention;

FIG. 5 is flow chart of a method for manufacturing the light receiving element for blue rays in accordance with one embodiment of the present invention;

FIGS. 6a to 6h are cross-sectional views illustrating a method for manufacturing the light receiving element for blue rays in accordance with one embodiment of the present invention;

FIG. 7 is a flow chart of a method for manufacturing a light receiving element for blue rays in accordance with another embodiment of the present invention; and

FIGS. 8a to 8g are cross-sectional views illustrating a method for manufacturing the light receiving element for blue rays in accordance with another embodiment of the present invention.

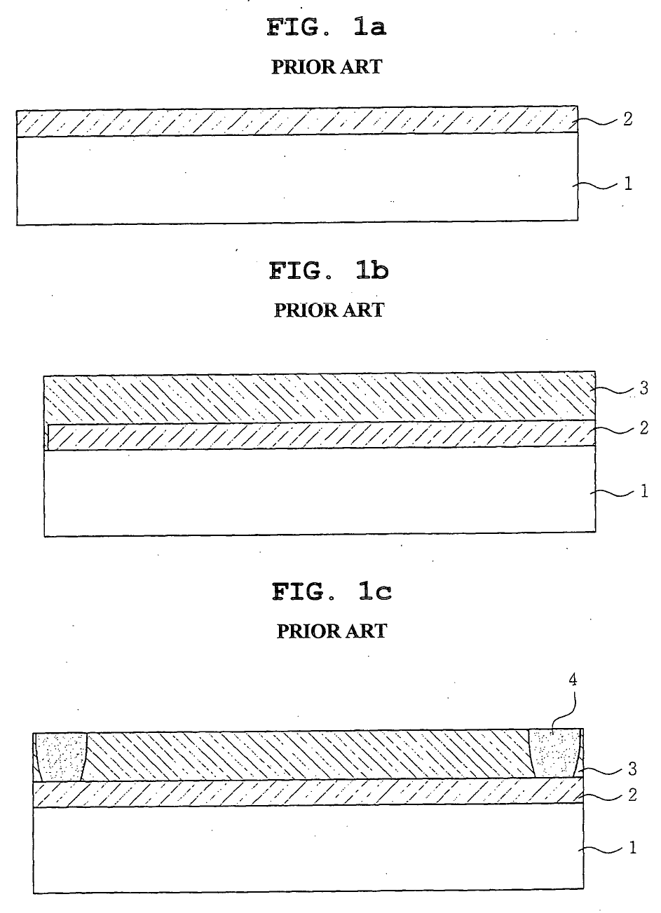

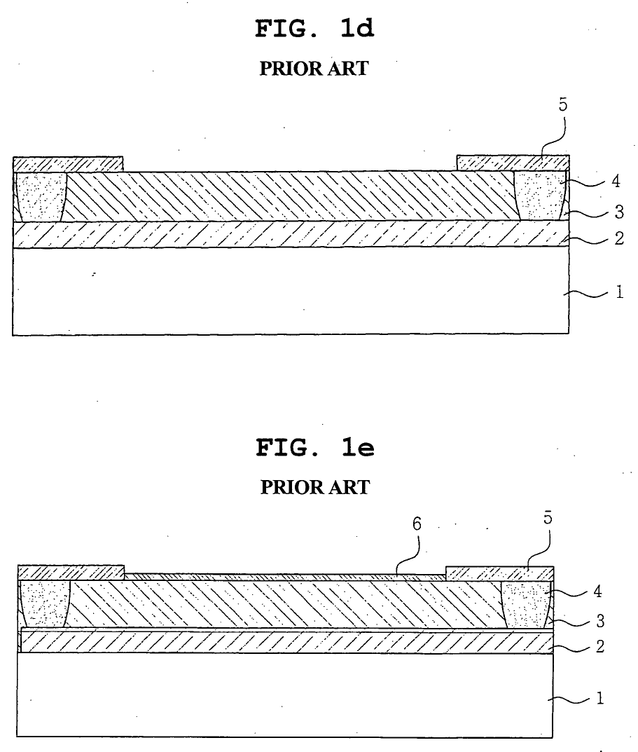

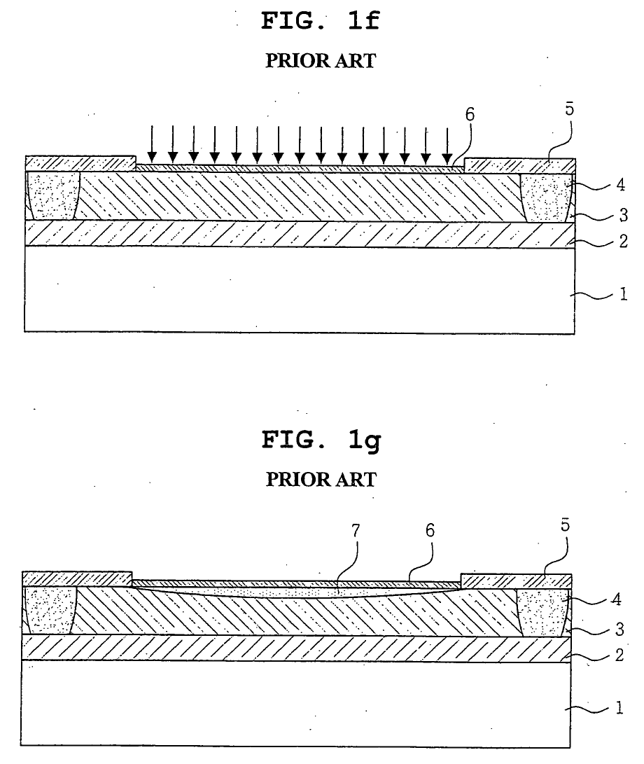

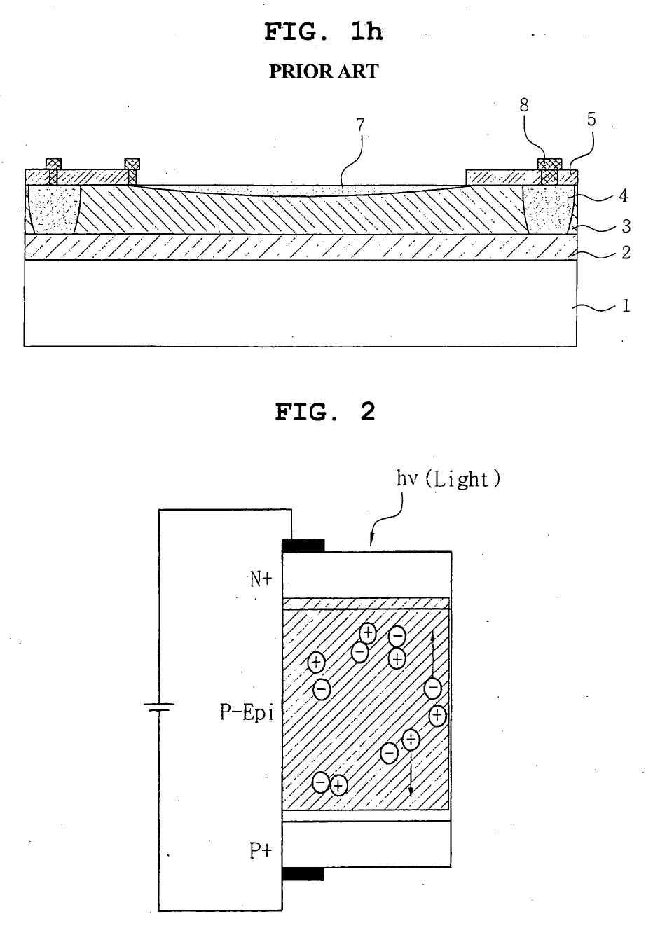

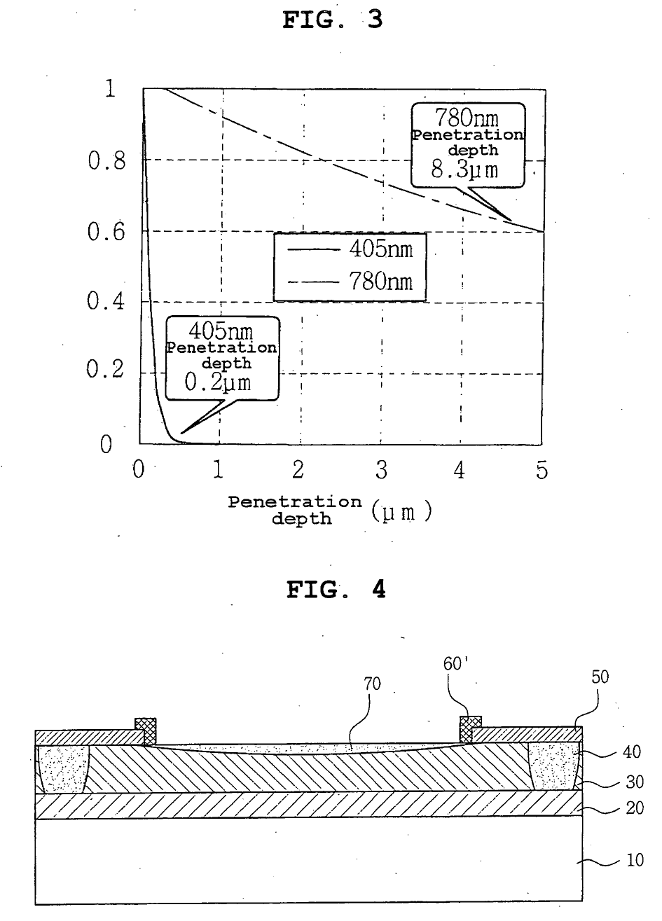

### DESCRIPTION OF THE PREFERRED EMBODIMENTS

Now, preferred embodiments of the present invention will be described in detail with reference to the annexed drawings.

First, constitution and operation of a light receiving element for blue rays in accordance with the present invention will be described in detail with reference to FIG. 4.

Here, FIG. 4 is a longitudinal-sectional view of a light receiving element for blue rays in accordance with one embodiment of the present invention.

The light receiving element of the present invention serves to convert light having a designated wavelength inputted from the exterior, more particularly, an optical signal having a wavelength of 405 nm for blue rays to an electric signal. As shown in FIG. 4, the light receiving element comprises a substrate 10, a p⁺ barrier layer (PBL) 20, a p-type epitaxial layer 30, a p⁺ well layer 40, an oxide layer 50, external electrodes 60′ made of a polysilicon layer 60, and an n⁺ shallow junction layer 70.

Here, the substrate 10 is a p⁺ silicon (Si) semiconductor substrate, and the p⁺ barrier layer (PBL) 20 is buried in the substrate 10 by a designated depth.

The p⁺ barrier layer (PBL) 20 is obtained by diffusing a designated impurity, more specifically, impurity such as boron (B), BF₂, or etc. into the substrate 10 and burying them in the substrate by a designated depth. The p⁺ barrier layer (PBL) 20 serves as an anode for receiving an actuation power provided from the exterior.

The p-type epitaxial layer 30 is an auto-doped layer obtained by performing high-resistance epitaxial growth of a designated impurity, and has a thickness of 1 μm to 10 μm and a resistivity of 1 Ωcm to 1,000 Ωcm.

Here, in case that a reverse bias voltage is applied to an area between the anode and the cathode, a depletion layer area for generating pairs of electrons-holes (EHP) corresponding to energy of incident light from the exterior is formed on the p-type epitaxial layer 30.

The p⁺ well layer 40 is formed by injecting a designated impurity, more specifically, impurity such as boron (B), BF₂, or etc. into areas of the p-type epitaxial layer 30, which are formed by a masking step for connection to the p⁺ barrier layer (PBL) 20, and then by heating the p-type epitaxial layer 30 containing the impurity to a designated temperature.

The oxide layer 50 is obtained by oxidizing the p-type epitaxial layer 30, thereby forming window areas on which polysilicon is deposited on the p-type epitaxial layer 30 by window-etching using a mask having a designated shape.

The polysilicon layer 60 is obtained by depositing polysilicon on areas, in which the window areas formed by window-etching the oxide layer 50 and the oxide layer 50 are overlapped, by a designated thickness.

Here, the polysilicon layer 60 formed on the overlapped areas between the window areas and the oxide layer 50 has a thickness of approximately 2,000 Å.

Portions 60′ of the polysilicon layer 60, formed on the overlapped areas between the window areas and the oxide layer 50, which are not removed by a subsequent etching process performed after the formation of the n⁺ shallow junction layer 70, serve as external electrodes for receiving a power provided from the exterior.

Accordingly, the light receiving element of the present invention is advantageous in that the light receiving element does not require a separate external electrode for receiving the external power and a process for manufacturing the light receiving element is simplified.

Thereafter, the polysilicon layer 60 obtained by depositing polysilicon on the overlapped areas between the window areas and the oxide layer 50 is doped with a designated impurity such as phosphorous (P), arsenic (As), or etc. by implanting the impurity into the polysilicon layer 60.

The n⁺ shallow junction layer 70 is obtained by heating the p-type epitaxial layer 30, doped with the impurity such as phosphorous (P), arsenic (As), or etc., at a designated temperature so that the impurity implanted into the polysilicon layer 60 is diffused into the p-type epitaxial layer 30 by a designated depth.

The n⁺ shallow junction layer 70 obtained by the above diffusion step into the designated depth of the p-type epitaxial layer 30 forms a junction depth of 0.1 μm to 0.2 μm, thus serving as a cathode for transmitting the electrical signal obtained by the photoelectric conversion to the exterior.

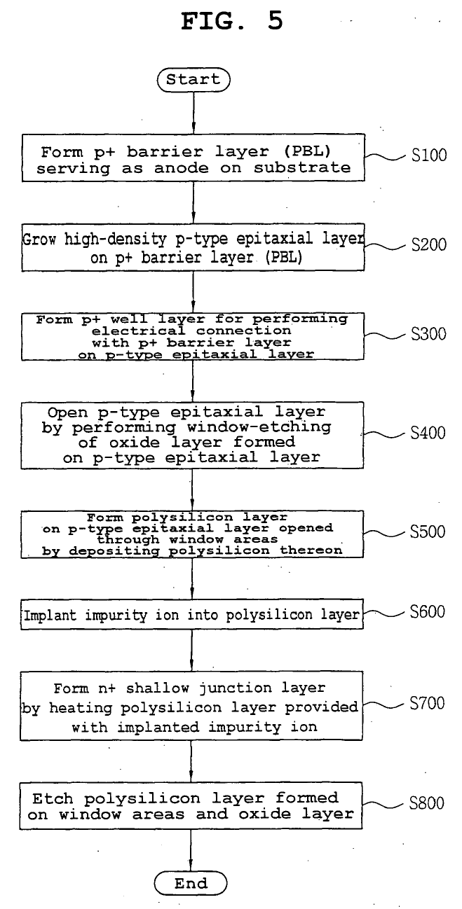

After the formation of the n⁺ shallow junction layer 70 into the designated depth of the p-type epitaxial layer 30 as described above, the polysilicon layer 60 formed on the overlapped areas between the window areas and the oxide layer 50 is removed by an etching step. Thereby, the light receiving element for blue rays having a vertical cross-sectional structure as shown in FIG. 5 is achieved.

Hereinafter, a method for manufacturing a light receiving element for blue rays in accordance with the present invention will be described in detail with reference to FIGS. 5 to 8.

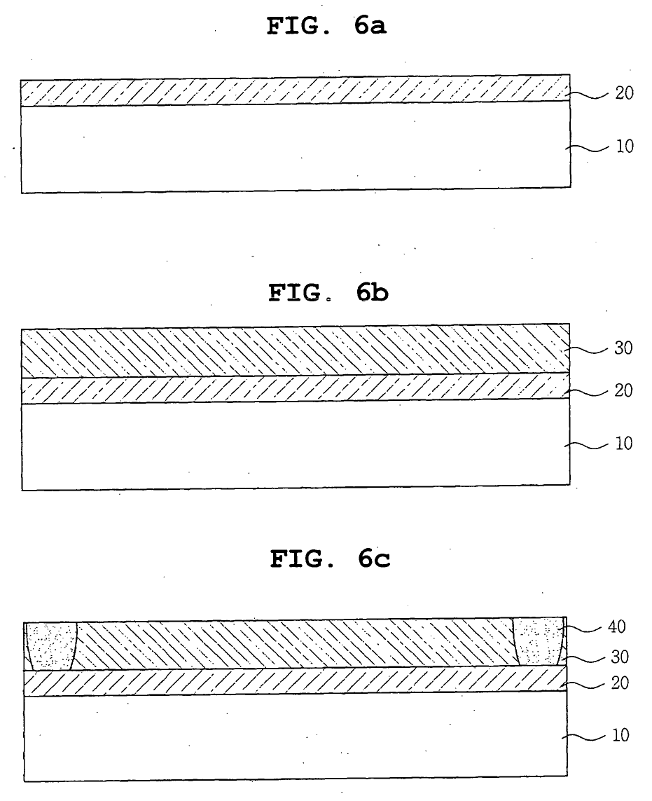

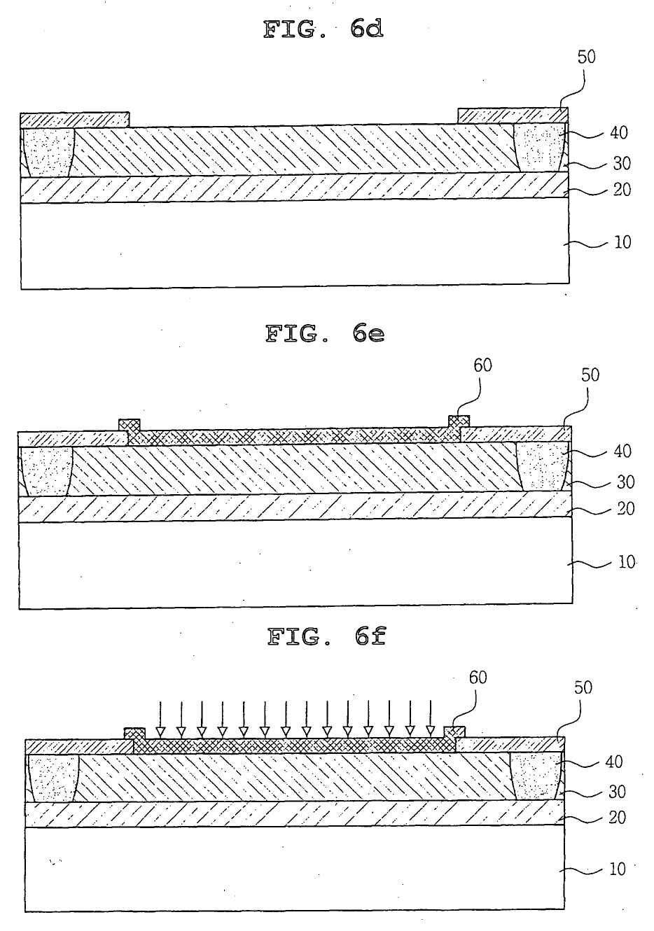

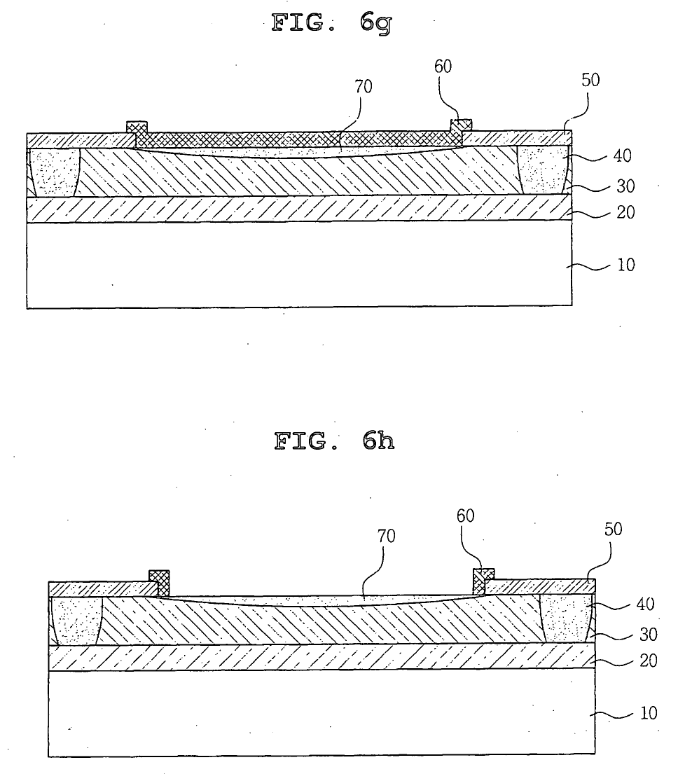

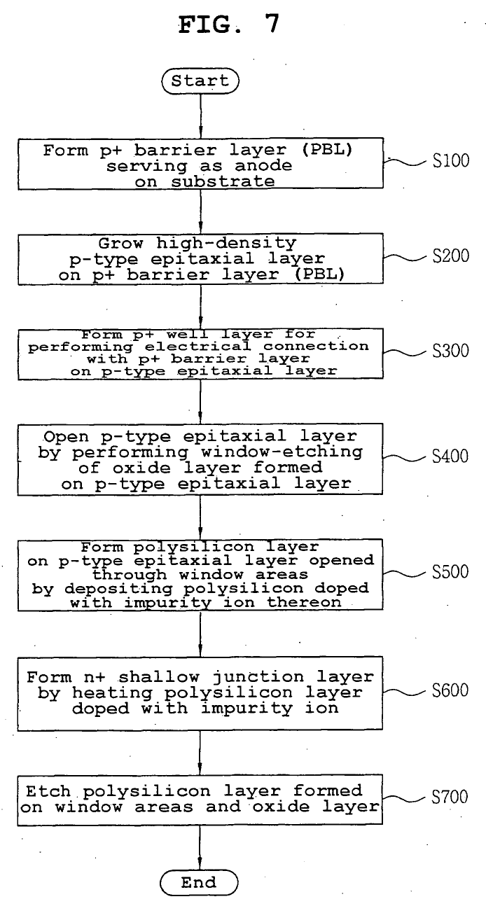

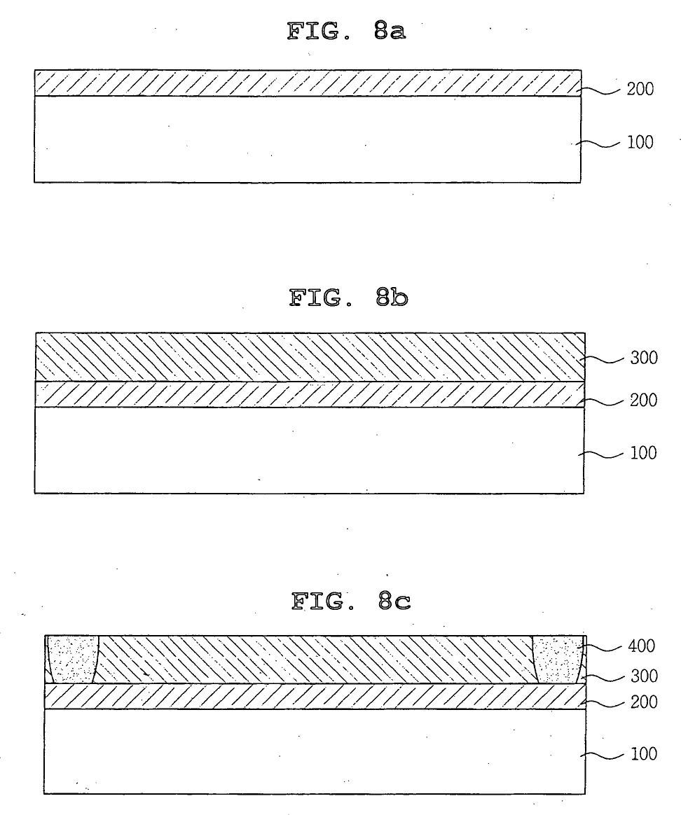

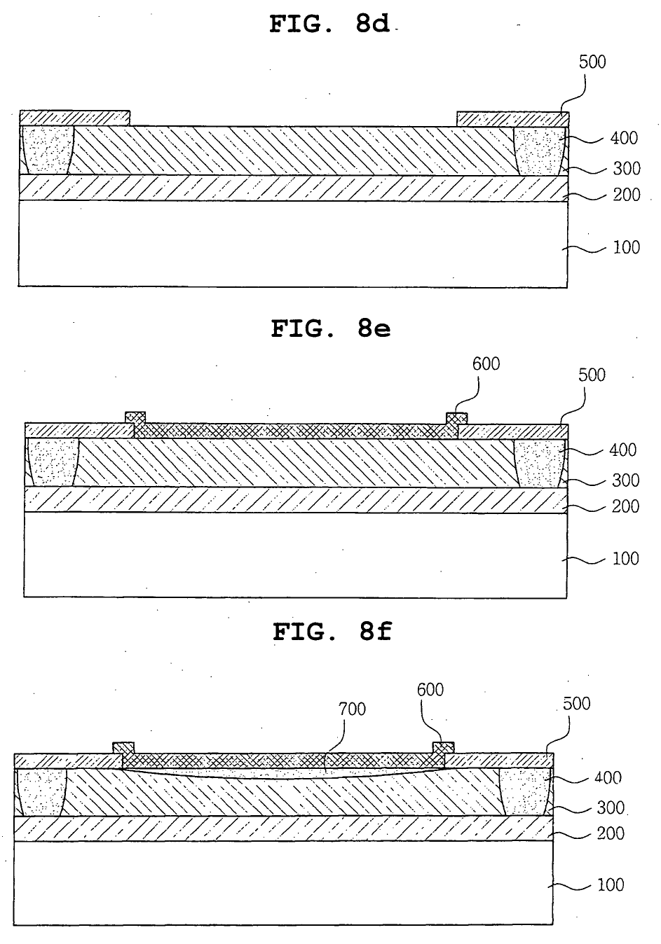

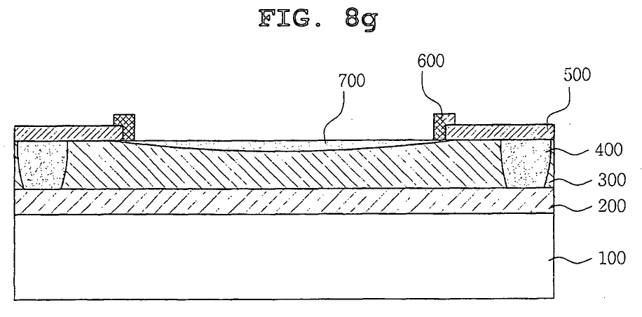

FIG. 5 is flow chart of a method for manufacturing a light receiving element for blue rays in accordance with one embodiment of the present invention. FIGS. 6a to 6h are cross-sectional views illustrating a method for manufacturing the light receiving element for blue rays in accordance with one embodiment of the present invention. FIG. 7 is a flow chart of a method for manufacturing a light receiving element for blue rays in accordance with another embodiment of the present invention. FIGS. 8a to 8g are cross-sectional views illustrating a method for manufacturing the light receiving element for blue rays in accordance with another embodiment of the present invention.

Now, a method for manufacturing a light receiving element for blue rays in accordance with one embodiment of the present invention will be described in detail with reference to FIGS. 5 and 6.

First, as shown in FIG. 5, the p⁺ barrier layer (PBL) 20 serving as an anode for receiving a power for actuating the light receiving element provided from the exterior is formed on the substrate 10 (S100).

More specifically with reference to FIG. 6a, the p⁺ barrier layer (PBL) 20 is buried in the substrate 10 by a designated depth by diffusing a designated impurity, more specifically, an impurity such as boron (B), BF₂, or etc. into the substrate 10 and then by heating the substrate 10 including the impurity at a designated temperature.

Here, the p⁺ barrier layer (PBL) 20 formed on the substrate 10 serves as the anode for receiving an actuation power provided from the exterior.

After the formation of the p⁺ barrier layer (PBL) 20 on the substrate 10, serving as the anode for receiving the actuation power provided from the exterior, as described above, the high-density p-type epitaxial layer 30 is grown on the p⁺ barrier layer (PBL) 20 by an epitaxial growth step, as shown in FIG. 5 (S200).

More specifically with reference to FIG. 6b, the p-type epitaxial layer 30 is grown on the p⁺ barrier layer (PBL) 20 by epitaxial-growing the designated impurity on the p⁺ barrier layer (PBL) 20, so that the grown p-type epitaxial layer 30 has a thickness of 1 μm to 10 μm and a resistivity of 1 Ωcm to 1,000 Ωcm.

In case that a reverse bias voltage is applied to the p-type epitaxial layer 30, a depletion layer area for generating pairs of electrons-holes (EHP) corresponding to energy of incident light from the exterior is formed on the p-type epitaxial layer 30.

After the growth of the p-type epitaxial layer 30 on the p⁺ barrier layer (PBL) 20, as described above, the p⁺ well layer 40, which is electrically connected to the p⁺ barrier layer (PBL) 20, is formed on designated areas of the p-type epitaxial layer 30 (S300).

More specifically with reference to FIG. 6c, areas for forming the p⁺ well layer 40 are formed by masking designated areas of the p-type epitaxial layer 30 and then exposing the areas to light.

Thereafter, the p⁺ well layer 40 is formed on the designated areas of the p-type epitaxial layer 30 by injecting a designated impurity, more specifically, an impurity such as boron (B), BF₂, or etc. into the above areas of the p-type epitaxial layer 30, and then by heating the p-type epitaxial layer 30 including the injected impurity at a designated temperature.

After the formation of the p⁺ well layer 40 on the designated areas of the p-type epitaxial layer 30, as described above, the p-type epitaxial layer 30 is opened through window areas for forming the polysilicon layer 60 by performing the window-etching of the oxide layer 50 formed by oxidizing the p-type epitaxial layer 30 (S400).

More specifically with reference to FIG. 6d, the oxide layer 50 is obtained by oxidizing the p-type epitaxial layer 30, and then the p-type epitaxial layer 30 is opened through the window areas for forming the polysilicon layer 60 formed by masking designated areas of the oxide layer 50, exposing the areas and then performing the window-etching of the areas.

After the opening of the p-type epitaxial layer 30 through the window areas formed at the designated areas of the oxide layer 50, as described above, the polysilicon layer 60 is formed on the overlapped areas between the window areas and the oxide layer 50 by depositing polysilicon thereon, as shown in FIG. 6e(S500).

Here, the deposition of polysilicon is performed such that the polysilicon layer 60 formed on the overlapped areas between the window areas and the oxide layer 50 has a thickness of approximately 0.2 μm.

After the formation of the polysilicon layer 60 on the overlapped areas between the window areas and the oxide layer 50, as described above, the polysilicon layer 60 is doped with a designated impurity such as phosphorous (P), arsenic (As), or etc. by implanting the impurity into the polysilicon layer 60, as shown in FIG. 6f (S600).

Thereafter, the n⁺ shallow junction layer 70 is formed on the p-type epitaxial layer 30 by a designated depth by heating the polysilicon layer 60 doped with the impurity, as shown in FIG. 6g(S700).

Here, the above n⁺ shallow junction layer 70 is formed by a diffusion step into a designated depth of the p-type epitaxial layer 30 so as to have a junction depth of 0.1 μm to 0.2 μm, thus serving as a cathode for transmitting an electrical signal obtained by the photoelectric conversion to the exterior.

After the formation of the n⁺ shallow junction layer 70 into the designated depth of the p-type epitaxial layer 30, as described above, the polysilicon layer 60 formed on the overlapped areas between the window areas and the oxide layer 50 is selectively removed by etching, thereby allowing the light receiving element of the present invention to be completed, as shown in FIG. 6h (S800).

Here, non-removed portions of the polysilicon layer 60 formed on the overlapped areas between the window areas and the oxide layer 50 serve as the external electrodes 60′ for receiving a power provided from the exterior.

Now, a method for manufacturing a light receiving element for blue rays in accordance with another embodiment of the present invention will be described in detail with reference to FIGS. 7 and 8.

Here, FIG. 7 is a flow chart of the method for manufacturing the light receiving element for blue rays in accordance with the above embodiment of the present invention, and FIGS. 8a to 8g are cross-sectional views illustrating the method for manufacturing the light receiving element for blue rays in accordance with the above embodiment of the present invention.

First, as shown in FIG. 7, the p⁺ barrier layer (PBL) 20 serving as an anode for receiving a power for actuating the light receiving element provided from the exterior is formed on the substrate 10 (S100).

More specifically with reference to FIG. 8a, the p⁺ barrier layer (PBL) 20 is buried in the substrate 10 by a designated depth by diffusing a designated impurity, more specifically, an impurity such as boron (B), BF₂, or etc. into the substrate 10 and then by heating the substrate 10 including the impurity at a designated temperature.

After the formation of the p⁺ barrier layer (PBĹ) 20 on the substrate 10, as described above, the high-density p-type epitaxial layer 30 is grown on the p⁺ barrier layer (PBL) 20 by an epitaxial growth step, as shown in FIG. 7 (S200).

More specifically with reference to FIG. 8b, the p-type epitaxial layer 30 is grown on the p⁺ barrier layer (PBL) 20 by epitaxial-growing the designated impurity on the p⁺ barrier layer (PBL) 20, so that the grown p-type epitaxial layer 30 has a thickness of 1 μm to 10 μm and a resistivity of 1 Ωcm to 1,000 Ωcm.

In case that a reverse bias voltage is applied to the p-type epitaxial layer 30, a depletion layer area for generating pairs of electrons-holes corresponding to energy of incident light from the exterior is formed on the p-type epitaxial layer 30.

After the growth of the p-type epitaxial layer 30 on the p⁺ barrier layer (PBL) 20, as described above, the p⁺ well layer 40, which is electrically connected to the p⁺ barrier layer (PBL) 20, is formed on designated areas of the p-type epitaxial layer 30, as shown in FIG. 7 (S300).

More specifically with reference to FIG. 8c, areas for forming the p⁺ well layer 40 are formed by masking designated areas of the p-type epitaxial layer 30 and then exposing the areas to light.

Thereafter, the p⁺ well layer 40 is formed on the designated areas of the p-type epitaxial layer 30 by injecting a designated impurity, more specifically, an impurity such as boron (B), BF₂, or etc. into the above areas of the p-type epitaxial layer 30, and then by heating the p-type epitaxial layer 30 including the injected impurity at a designated temperature.

After the formation of the p⁺ well layer 40 on the p-type epitaxial layer 30, as described above, the p-type epitaxial layer 30 is opened through window areas for forming the polysilicon layer 60 by performing the window-etching of the oxide layer 50 formed by oxidizing the p-type epitaxial layer 30 (S400).

After the opening of the p-type epitaxial layer 30 through the window areas formed at the designated areas of the oxide layer 50, as described above, the polysilicon layer 60 is formed on the overlapped areas between the window areas and the oxide layer 50 by depositing polysilicon, doped with a designated impurity such as phosphorous (P), arsenic (As), or etc., on the overlapped areas, as shown in FIG. 8e (S500).

Here, the deposition of polysilicon is performed such that the polysilicon layer 60, doped with the impurity, formed on the overlapped areas between the window areas and the oxide layer 50 has a thickness of approximately 0.2 μm.

After the formation of the polysilicon layer 60, doped with the impurity, on the overlapped areas between the window areas and the oxide layer 50, as described above, the n⁺ shallow junction layer 70 is formed on the p-type epitaxial layer 30 by a designated depth by heating the polysilicon layer 60 doped with the impurity, as shown in FIG. 8f (S600).

Here, the above n⁺ shallow junction layer 70 is formed by a diffusion step into a designated depth of the p-type epitaxial layer 30 so as to have a junction depth of 0.1 μm to 0.2 μm, thus serving as a cathode for transmitting an electrical signal obtained by the photoelectric conversion to the exterior.

After the formation of the n⁺ shallow junction layer 70 into the designated depth of the p-type epitaxial layer 30, as described above, the polysilicon layer 60 formed on the overlapped areas between the window areas and the oxide layer 50 is selectively removed by etching, thereby allowing the light receiving element of the present invention to be completed, as shown in FIG. 8g (S700).

Here, non-removed portions of the polysilicon layer 60 formed on the overlapped areas between the window areas and the oxide layer 50 serve as the external electrodes 60′ for receiving a power provided from the exterior.

As apparent from the above description, the present invention provides a light receiving element for blue rays, of which a junction depth becomes shallow so as to easily receive the blue rays having a short wavelength with a short penetration depth, and a method for manufacturing the light receiving element, thus improving photoelectric conversion efficiency.

Further, the light receiving element for blue rays of the present invention comprises a polysilicon layer serving as an external electrode, thus not requiring a step for forming a separated external electrode and simplifying a manufacturing process.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A light receiving element for blue rays comprising:
a substrate;
a p⁺ barrier layer (PBL) buried in the substrate by a designated depth for serving as an anode for receiving a power provided from the exterior;
a p-type epitaxial layer formed on the p⁺ barrier layer (PBL) by epitaxial growth, and provided with a depletion layer area for generating pairs of electrons-holes (EHP) corresponding to energy of incident light from the exterior;
a p⁺ well layer formed on designated areas of the p-type epitaxial layer, formed by masking, by injecting a designated impurity in an ion state into the designated areas, and electrically connected to the p⁺ barrier layer (PBL);
a polysilicon layer formed by depositing polysilicon on window areas formed by window-etching an oxide layer obtained by oxidizing the p-type epitaxial layer; and
an n⁺ shallow junction layer diffused into a designated depth of the p-type epitaxial layer by implanting a designated impurity ion into the polysilicon layer and then heating the polysilicon layer for serving as a cathode for transmitting an electrical signal obtained by photoelectric conversion to the exterior.

2. A light receiving element for blue rays comprising:
a substrate;
a p⁺ barrier layer (PBL) buried in the substrate by a designated depth for serving as an anode for receiving a power provided from the exterior;
a p-type epitaxial layer formed on the p⁺ barrier layer (PBL) by epitaxial growth, and provided with a depletion layer area for generating pairs of electrons-holes (EHP) corresponding to energy of incident light from the exterior;
a p⁺ well layer formed on designated areas of the p-type epitaxial layer, formed by masking, by injecting a designated impurity in an ion state into the designated areas, and electrically connected to the p⁺ barrier layer (PBL);
a polysilicon layer formed by depositing polysilicon, doped with an impurity ion, on window areas formed by window-etching an oxide layer obtained by oxidizing the p-type epitaxial layer; and
an n⁺ shallow junction layer diffused into a designated depth of the p-type epitaxial layer by heating the polysilicon layer for serving as a cathode for transmitting an electrical signal obtained by photoelectric conversion to the exterior.

3. The light receiving element as set forth in claim 1 or 2, wherein:
the polysilicon layer is overlapped with the oxide layer by a designated distance; and
parts of the polysilicon layer formed on the window areas and the oxide layer are removed by etching after the formation of the n⁺ shallow junction layer.

4. The light receiving element as set forth in claim 1 or 2,
wherein non-removed portions of the polysilicon layer formed on the window areas and the oxide layer serve as external electrodes for receiving a power provided from the exterior.

5. The light receiving element as set forth in claim 1 or 2,
wherein the impurity ion-injected into the p⁺ well layer is one selected from the group consisting of boron (B) and BF₂.

6. The light receiving element as set forth in claim 1 or 2,
wherein the n⁺ shallow junction layer has a junction depth of 0.1 μm to 0.2 μm.

7. The light receiving element as set forth in claim 1 or 2,
wherein the impurity ion forming the n⁺ shallow junction layer is one selected from the group consisting of phosphorous (P) and arsenic (As).

8. A method for manufacturing a light receiving element for blue rays comprising the steps of:
(a) forming a p⁺ barrier layer (PBL) for serving as an anode for receiving a power provided from the exterior on a substrate;
(b) growing a p-type epitaxial layer, provided with a depletion layer area for generating pairs of electrons-holes (EHP) corresponding to energy of incident light from the exterior, on the p⁺ barrier layer (PBL);
(c) forming a p⁺ well layer, electrically connected to the p⁺ barrier layer (PBL), on the p-type epitaxial layer;
(d) forming an oxide layer by oxidizing the p-type epitaxial layer;
(e) forming a polysilicon layer by depositing polysilicon on overlapped areas between window areas formed by window-etching the oxide layer and the oxide layer by a designated distance;
(f) implanting a designated impurity ion into the polysilicon layer;
(g) forming an n⁺ shallow junction layer into a designated depth of the p-type epitaxial layer by heating the polysilicon layer provided with the implanted impurity ion; and
(h) etching the polysilicon layer formed on the overlapped areas between window areas and the oxide layer by the designated distance.

9. A method for manufacturing a light receiving element for blue rays comprising the steps of:
(a) forming a p⁺ barrier layer (PBL) for serving as an anode for receiving a power provided from the exterior on a substrate;
(b) growing a p-type epitaxial layer, provided with a depletion layer area for generating pairs of electrons-holes (EHP) corresponding to energy of incident light from the exterior, on the p⁺ barrier layer (PBL);
(c) forming a p⁺ well layer, electrically connected to the p⁺ barrier layer (PBL), on the p-type epitaxial layer;
(d) forming an oxide layer by oxidizing the p-type epitaxial layer;
(e) forming a polysilicon layer by depositing polysilicon, doped with an impurity ion, on overlapped areas between window areas formed by window-etching the oxide layer and the oxide layer by a designated distance;
(f) forming an n⁺ shallow junction layer into a designated depth of the p-type epitaxial layer by heating the polysilicon layer doped with the impurity ion; and
(g) etching the polysilicon layer formed on the overlapped areas between window areas and the oxide layer by the designated distance

10. The method as set forth in claim 8 or 9,
wherein the n⁺ shallow junction layer has a junction depth of 0.1 μm to 0.2 μm.
